(19) United States
(12) Patent Application Publication
(10) Pub. No.: US 2010/0225417 A1
(43) Pub. Date: Sep. 9, 2010

(54) N-Way Divider/Combiner, With N Different From A Power Of Two, Obtained In Planar, Monolithic, And Single-Face Technology For Distribution Networks For Avionic Radars With Electronic Beam-Scanning Antenna

(75) Inventors: Antonino Mistretta, Palermo (IT); Antonino Spatola, Palermo (IT)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Selex Galileo S.p.A.

(21) Appl. No.: 12/716,452

(22) Filed: Mar. 3, 2010

(30) Foreign Application Priority Data
Mar. 3, 2009 (IT) TO2009A000160

(51) Int. Cl. H01P 5/12; H01P 11/00; G03F 7/20

(52) U.S. Cl. 333/128; 216/13; 430/312

(57) ABSTRACT

A planar N-way power divider/combiner, wherein N is an integer different from a power of two, comprising a first port, which is to be coupled to a first transmission line having a first characteristic impedance, N second ports, which are to be coupled each to a corresponding electrical load, and N division/combination branches, each coupled between the first port and a corresponding second port and each having a first stage, a second stage, and an intermediate node between the two stages. All the electrical loads have one and the same given load impedance. For each pair of planarly adjacent division/combination branches, a corresponding first uncoupling resistor is coupled between corresponding intermediate nodes and a corresponding second uncoupling resistor is coupled between the corresponding second ports.

The present invention relates to an N-way divider/combiner, with N different from a power of two (N≠2^{K}, with K=1,2,3,4, . . . ), obtained in totally planar, monolithic, and single-face technology. In particular, the present invention finds advantageous, though non-exclusive, application in distribution networks for radiofrequency (RF) signals of avionic radars with electronic beam-scanning antenna.

### BACKGROUND OF THE INVENTION

As is known, in modern radar systems, in particular in modern avionic radars, the requirements for locating targets and for security and surveillance have led to the use of electronic beam-scanning active phased-array antennas.

In particular, avionic radars based upon electronic beam-scanning active phased-array antennas comprise, as key elements, a plurality of transceiver (T/R) modules, each of which is coupled to a corresponding radiator.

Furthermore, generally, said radars comprise a distribution network, which enables, in transmission, distribution of transmission power to the T/R modules, and, in reception, combination of the signals received.

In this regard, schematically illustrated in FIG. 1 is an example of architecture of an avionic radar 10, which comprises an electronic beam-scanning active phased-array antenna.

In particular, the avionic radar 10 comprises a distribution network, or manifold 11, which in FIG. 1 is indicated as a whole by a dotted line and comprises, in turn, a port 12 coupled to a horizontal combiner 13, which is in turn coupled to a plurality of vertical combiners 14.

Each vertical combiner 14 is further coupled to a plurality of T/R modules 15, each of which is coupled to a corresponding radiator 16.

In detail, the distribution network 11 enables, in transmission, propagation of an RF signal from the port 12 to the T/R modules 15, and, in reception, propagation from the T/R modules 15 to the port 12 of respective RF signals received from the radiators 16.

Consequently, as may be readily appreciated, the distribution network 11 must necessarily comprise one or more radiofrequency (RF) power dividers/combiners, which will enable:
in transmission, division of an RF signal present on the port 12 and having a power equal to P, into a number N of RF signals, wherein N is the number of T/R modules 15, i.e., of radiators 16, of the avionic radar 10, each of the N RF signals having a corresponding power equal to P/N and being inputted, by the distribution network 11, to a corresponding T/R module 15; and
in reception, combination of N RF signals received, each, from a corresponding radiator 16, said combination resulting in an RF combined signal supplied by the distribution network 11 on the port 12.

As is known, radiofrequency (RF) power most widely used dividers/combiners are Wilkinson dividers/combiners since they guarantee optimal performance in terms of reduction of transmission and reflection losses, phase and amplitude matching of the RF signals at the output ports and insulations between the N channels into which the input signal is divided.

In this respect, FIG. 2 illustrates a typical circuit diagram of a Wilkinson divider/combiner 20 with two ways, i.e., with N=2.

In detail, the Wilkinson divider/combiner 20 comprises:
a first port P₁, coupled to a first transmission line 21 having a characteristic impedance Z₀;
a second port P₂, coupled to a first electrical load 22 having an impedance equal to said characteristic impedance Z₀;
a third port P₃, coupled to a second electrical load 23 having an impedance equal to said characteristic impedance Z₀;
a second transmission line 201, coupled between the first port Pᵢ and the second port P₂ and having a characteristic impedance equal to \sqrt{2}Z₀ and an electrical length equal to λ/4, wherein λ is the wavelength corresponding to the middle frequency of the frequency band of the RF signals for the propagation of which the Wilkinson divider/combiner 20 is designed;
a third transmission line 202, coupled between the first port P₁ and the third port P₃ and having a characteristic impedance equal to \sqrt{2}Z₀ and an electrical length equal to λ/4; and
a resistance 203 equal to 2Z₀, coupled between the second port P₂ and the third port P₃ and having the task of uncoupling the second transmission line 201 and the third transmission line 202 from one another.

The Wilkinson divider/combiner 20 enables an ideal power division to be obtained. In fact, if on the first port P₁ an RF signal having a power P, is present, then on each of the ports P₂ and P₃ there will be a corresponding RF signal having a respective power P₀ equal to P/2.

In the case wherein an avionic radar with electronic beam-scanning antenna presents the need for a power division/combination equal to N=2^{K}, with K=1,2,3,4, . . . , the corresponding manifold of the avionic radar comprises K Wilkinson dividers/combiners 20 arranged in cascaded fashion, whereas, when the power division/combination is equal to N≠2^{K}, the use of Wilkinson dividers/combiners presents some problems.

In this respect, FIG. 3 illustrates a typical circuit diagram of a Wilkinson divider/combiner 30 with 3 ways, i.e., with N=3.

In detail, the Wilkinson divider/combiner 30 comprises:
a first port P₁, coupled to a first transmission line 31 having a characteristic impedance Z₀;
a second port P₂, coupled to a first electrical load 32 having an impedance equal to said characteristic impedance Z₀;
a third port P₃, coupled to a second electrical load 33 having an impedance equal to said characteristic impedance Z₀;
a fourth port P₄, coupled to a third electrical load 34 having an impedance equal to said characteristic impedance Z₀;
a second transmission line 301, coupled between the first port Pᵢ and the second port P₂ and having a characteristic impedance equal to \sqrt{3}Z₀ and an electrical length equal to λ/4, wherein λ is the wavelength corresponding to the middle frequency of the frequency band of the RF signals for the propagation of which the Wilkinson divider/combiner 30 is designed;
a third transmission line 302, coupled between the first port P₁ and the third port P₃ and having a characteristic impedance equal to \sqrt{3}Z₀ and an electrical length equal to λ/4;
a fourth transmission line 303, coupled between the first port P₁ and the fourth port P₄ and having a characteristic impedance equal to \sqrt{3}Z₀ and an electrical length equal to λ/4;
a first resistance 304 equal to 3Z₀, coupled between the second port P₂ and the third port P₃;
a second resistance 305 equal to 3Z₀, coupled between the third port P₃ and the fourth port P₄; and
a third resistance 306 equal to 3Z₀, coupled between the second port P₂ and the fourth port P₄.

The resistances 304, 305 and 306 have the task of uncoupling the second transmission line 301, the third transmission line 302, and the fourth transmission line 303 from one another.

The Wilkinson divider/combiner 30 enables an ideal power division to be obtained. In fact, if at the first port P₁ an RF signal having a power P, is present, then on each of the ports P₂, P₃ and P₄ there will be a corresponding RF signal having a respective power P₀ equal to P/3.

In the case wherein the power division is equal to N≠2^{K} with N>3, the Wilkinson topology becomes complicated considerably in terms of circuit diagram, also on account of the presence of the uncoupling resistors.

In avionic radars with electronic beam-scanning antenna, a fundamental target is the production of N-way, bidirectional, power dividers/combiners obtained in totally planar, monolithic, and single-face technology. This derives from the possibility of “stacking” easily the radiofrequency distribution networks that join the arrays of radiators.

Furthermore, said dividers/combiners must present optimal performance in terms of balancing of amplitude and phase and of insulations and losses by transmission and reflection.

In fact, said dividers/combiners must drive the RF signal towards the T/R modules, and the performance referred to above considerably affects the radiation pattern.

When the number of ports to be driven is N=2^{K}, the Wilkinson topology described previously proves to be the most suitable and compliant with the requirements discussed for said applications.

When instead, said number of ports is N≠2^{K}, for example on account of requirements deriving from considerations linked to electronic counter-counter measures (ECCMs), the Wilkinson topology manages to guarantee high levels of electrical performance, but cannot be developed in planar technology.

This is caused by the presence of the uncoupling resistors, which, as may be readily inferred from FIG. 3, cannot be distributed all in a single plane.

On the other hand, other topologies of planar power dividers/combiners have been developed in the course of the years, but none manages to guarantee the electrical performance of the Wilkinson topology.

In fact, the applications in which planar dividers/combiners are used that have been developed up to now are, for the most part, aimed at combinations of power amplifiers, for which, unlike avionic radars with electronic beam-scanning antenna, a slight degradation of the electrical performance is acceptable.

Considering the constraint of a planar solution that enables a compact profile, a reduced weight, and a low cost to be obtained for the entire avionic radar with electronic beam-scanning antenna, when the number of ports of the manifold of the avionic radar is equal to N≠2^{K}, up to now two solutions have been possible, both based upon the use of Wilkinson dividers/combiners, which, as has just been said, are the dividers/combiners that so far offer the best electrical performance among all the existing planar dividers/combiners.

A first solution envisages the use of an M-way Wilkinson divider/combiner with M=2^{L}>N, in which each of the M−N=2^{L}−N unused output ports is closed on a respective traditional standard electrical load of 50 Ω.

For example, if the number N of output ports of the manifold of the avionic radar with electronic beam-scanning antenna must be equal to 20, a Wilkinson divider/combiner can be used with M=32 ways, in which each of the M−N=32−20=12 unused output ports is closed on a respective traditional standard electrical load of 50 Ω.

Said solution hence presents the marked disadvantage of a considerable power loss on the matched loads.

A second solution, instead, is that of using a cascade of two-way Wilkinson dividers/combiners unbalanced in amplitude and phase.

In this respect, FIG. 4 is a schematic illustration of an example, which is self-explicative for a person skilled in the art, of a manifold 40 of an avionic radar with electronic beam-scanning antenna having twenty output ports and comprising a cascade of two-way Wilkinson dividers/combiners unbalanced in amplitude and phase.

From FIG. 4 it may be readily understood how the presence of different paths for the RF signals that propagate along the manifold 40 will cause a marked unbalancing in phase and amplitude on the twenty output ports and consequently a considerable degradation of the radiation pattern of the radar.

### SUMMARY OF THE INVENTION

The aim of the present invention is hence to provide an N-way divider/combiner, with N≠2^{K}, which, in general, will be able to alleviate the disadvantages just referred to, and which, in particular, can be obtained in totally planar, monolithic, and single-face technology and will present excellent performance in terms of balancing of amplitude and phase and of insulations and losses by transmission and reflection.

The aforesaid aim is achieved by the present invention in so far as it regards an N-way divider/combiner, with N≠2^{K}, and a method for the production of an N-way divider/combiner, with N≠2^{K}, as defined in the attached claims.

### BRIEF DESCRIPTION OF THE DRAWINGS

For a better understanding of the present invention, some preferred embodiments, provided purely by way of explanatory and non-limiting example, will now be illustrated with reference to the annexed drawings (which are not in scale), wherein:

FIG. 1 is a schematic illustration of an example of architecture of an electronic beam-scanning avionic radar;

FIG. 2 shows a typical circuit diagram of a two-way Wilkinson divider;

FIG. 3 shows a typical circuit diagram of a three-way Wilkinson divider;

FIG. 4 is a schematic illustration of a manifold of an avionic radar with electronic beam-scanning antenna having twenty output ports and comprising a cascade of 2-way Wilkinson dividers unbalanced in amplitude and phase;

FIG. 5 shows a circuit diagram of a 3-way power divider/combiner according to the present invention;

FIG. 6 shows a circuit diagram of a 5-way power divider/combiner according to the present invention;

FIG. 7 shows a cross section of a multilayer structure with which an N-way power divider/combiner, with N≠2^{K}, according to the present invention, may be produced;

FIG. 8 shows a top plan view of the 3-way power divider/combiner obtained in totally planar, monolithic, and single-face technology, the circuit diagram of which is illustrated in FIG. 5; and

FIG. 9 shows a top plan view of the 5-way power divider/combiner obtained in totally planar, monolithic, and single-face technology, the circuit diagram of which is illustrated in FIG. 6.

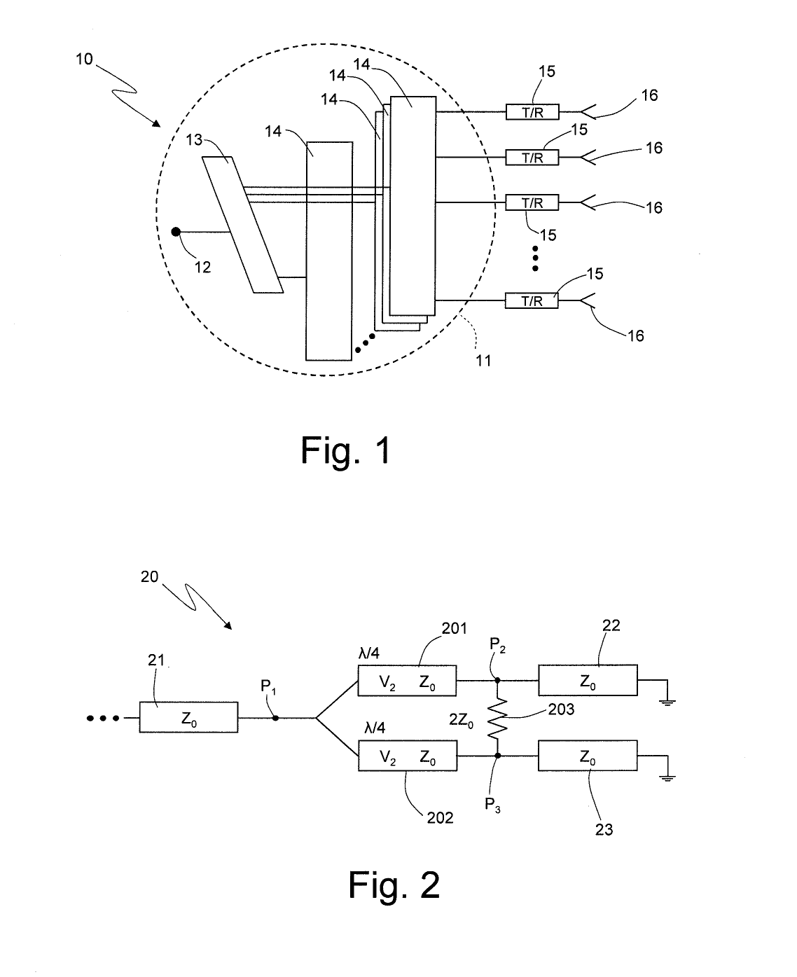

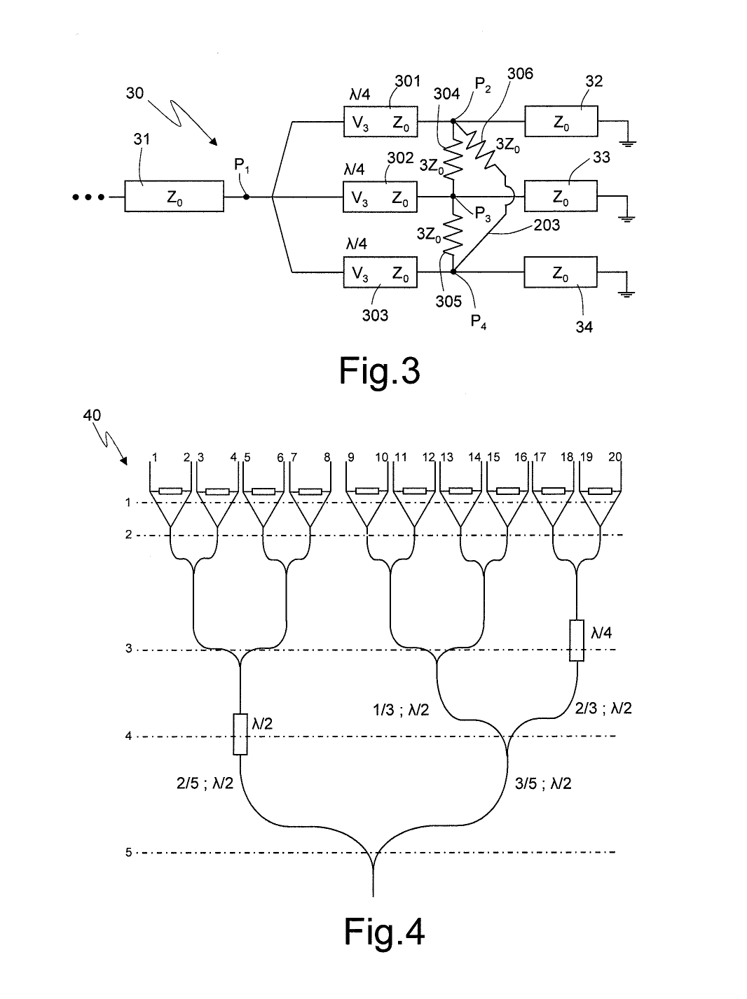

### DETAILED DESCRIPTION OF THE DRAWINGS

The ensuing description is provided to enable a person skilled in the art to reproduce and use the invention. Various modifications to the embodiments presented will be immediately evident to persons skilled in the art, and the generic principles disclosed herein could be applied to other embodiments and applications without thereby departing from the scope of the present invention.

Hence, the present invention is not to be understood as limited just to the embodiments described and illustrated, but it must be granted the widest scope consistently with the principles and characteristics presented and defined in the annexed claims.

The present invention derives from an in-depth study conducted by the present applicant in order to investigate the possibility of providing an N-way divider/combiner, with N≠2^{K}, in totally planar, monolithic, and single-face technology that is able to guarantee high levels of electrical performance at radio frequency. The result of said in-depth study is the N-way divider/combiner, with N≠2^{K}, which is described in what follows.

In particular, a planar N-way divider/combiner, with N≠2^{K}, according to the present invention has a multi-stage forklike structure, preferably a double-stage forklike structure, with uncoupling resistances on each stage.

In detail, provided according to the present invention is an N-way power divider/combiner, wherein N is an integer different from a power of two (N≠2^{K}, with K=1,2,3,4, . . . ), comprising:
a first port, which is to be coupled to a first transmission line having a first characteristic impedance;
N second ports, which are to be coupled each to a corresponding electrical load, all the electrical loads having one and the same given load impedance; and
N division/combination branches, each coupled between the first port and a corresponding second port.

Furthermore, the power divider/combiner is configured for:
dividing a first electrical signal present on the first port into N second electrical signals;
supplying each of the N second electrical signals on a corresponding second port;
combining N third electrical signals present each on a corresponding second port in a fourth electrical signal; and
supplying said fourth electrical signal at the first port.

The power divider/combiner according to the present invention is characterized:
in that each of the N division/combination branches comprises a corresponding first stage, a corresponding second stage, and a corresponding intermediate node between the corresponding first stage and the corresponding second stage; and
in that it also comprises, for each pair of adjacent division/combination branches, a corresponding first uncoupling resistor coupled between the corresponding intermediate nodes, and a corresponding second uncoupling resistor coupled between the corresponding second ports.

Preferably, the first electrical signal has a first power and a first frequency comprised in a given frequency band, and all the N second electrical signals have the first frequency and one and the same second power equal to the first power divided by N.

Furthermore, all the N third electrical signals have one and the same third power and one and the same second frequency comprised in the given frequency band, and the fourth electrical signal has the second frequency and a fourth power equal to N times the third power.

Preferably, all the first uncoupling resistors have one and the same first electrical resistance, and all the second uncoupling resistors have one and the same second electrical resistance.

Furthermore, in each of the N division/combination branches the corresponding first stage comprises a corresponding second transmission line coupled between the first port and the corresponding intermediate node, and the corresponding second stage comprises a corresponding third transmission line coupled between the corresponding intermediate node and the corresponding second port. All the second transmission lines have one and the same second characteristic impedance and one and the same first electrical length, and all the third transmission lines has one and the same third characteristic impedance and one and the same second electrical length. The first electrical length is an odd integer multiple of one quarter of a predefined wavelength that corresponds to a middle frequency of the given frequency band, and the second electrical length is an odd integer multiple of one quarter of the predefined wavelength.

To clarify better the structure of the N-way divider/combiner, with N≠2^{K}, according to the present invention, described by way of example in what follows is a three-way divider/combiner according to the present invention.

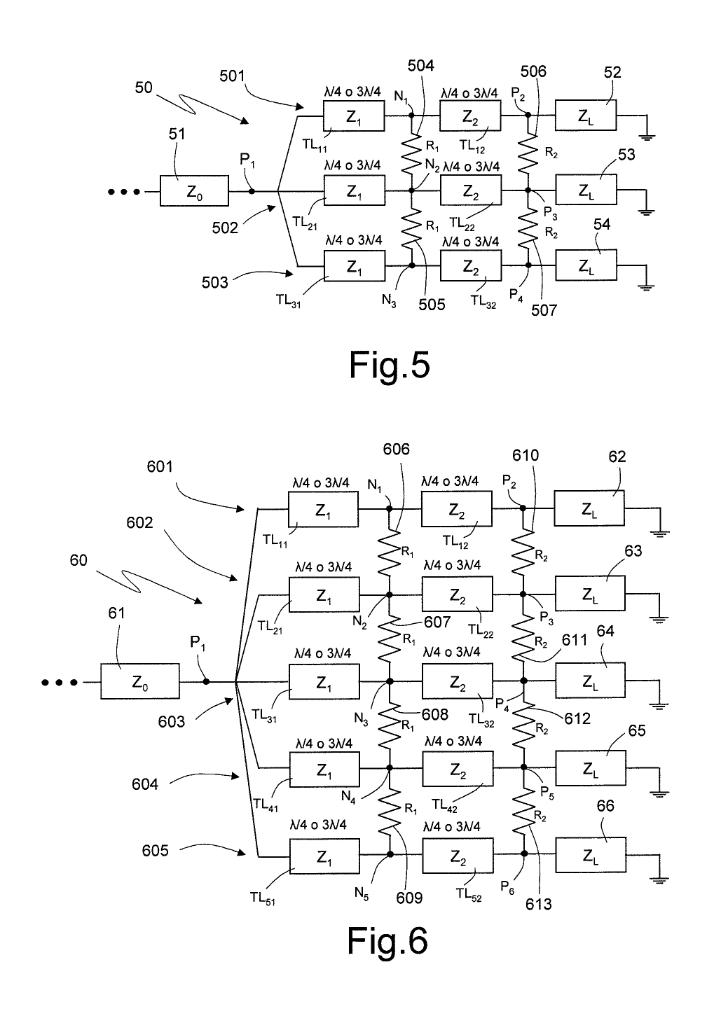

In particular, illustrated in FIG. 5 is a circuit diagram of a three-way divider/combiner 50 according to the present invention.

In detail, the divider/combiner 50 functions in a frequency band comprised between 8.5 GHz and 10 GHz and, as illustrated in FIG. 5, comprises:
a first port P₁, coupled to a first transmission line 51 having a characteristic impedance Z₀;
a second port P₂, coupled to a first electrical load 52 having an impedance Z_{L};
a third port P₃, coupled to a second electrical load 53 having the impedance Z_{L};
a fourth port P₄, coupled to a third electrical load 54 having the impedance Z_{L};
a first division/combination branch 501, coupled between the first port P₁ and the second port P₂;
a second division/combination branch 502, coupled between the first port P₁ and the third port P₃; and
a third division/combination branch 503, coupled between the first port P₁ and the fourth port P₄.

Furthermore, the first division/combination branch 501 is divided into a first stage TL₁₁ and a second stage TL₁₂ and comprises an intermediate node N₁, the first stage TL₁₁ being constituted by a transmission line coupled between the first port P₁ and the intermediate node N₁ and having a characteristic impedance equal to Z₁ and an electrical length equal to λ/4 or 3λ/4, wherein λ is the wavelength corresponding to the middle frequency of the frequency band [8.5 GHz; 10 GHz] of the RF signals for the propagation of which the divider/combiner 50 has been designed, the second stage TL₁₂ being constituted by a transmission line coupled between the intermediate node N₁ and the second port P₂ and having a characteristic impedance equal to Z₂ and an electrical length equal to λ/4 or 3λ/4.

Also the second division/combination branch 502 is divided into a first stage TL₂₁ and a second stage TL₂₂ and comprises an intermediate node N₂, the first stage TL₂₁ being constituted by a transmission line coupled between the first port P₁ and the intermediate node N₂ and having the characteristic impedance Z₁ and an electrical length equal to λ/4 or 3λ/4, the second stage TL₂₂ being constituted by a transmission line coupled between the intermediate node N₂ and the third port P₃ and having the characteristic impedance Z₂ and an electrical length equal to λ/4 or λ/4.

Furthermore, also the third division/combination branch 503 is divided into a first stage TL₃₁ and a second stage TL₃₂ and comprises an intermediate node N₃, the first stage TL₃₁ being constituted by a transmission line coupled between the first port P₁ and the intermediate node N₃ and having the characteristic impedance Z₁ and an electrical length equal to λ/4 or 3λ/4, the second stage TL₃₂ being constituted by a transmission line coupled between the intermediate node N₃ and the fourth port P₄ and having the characteristic impedance Z₂ and an electrical length equal to λ/4 or 3λ/4.

Finally, the divider/combiner 50 also comprises:
a first uncoupling resistor 504, coupled between the intermediate node N₁ and the intermediate node N₂ and having an electrical resistance equal to R₁;
a second uncoupling resistor 505, coupled between the intermediate node N₂ and the intermediate node N₃ and having the electrical resistance R₁;
a third uncoupling resistor 506, coupled between the second port P₂ and the third port P₃ and having an electrical resistance equal to R₂; and
a fourth uncoupling resistor 507, coupled between the third port P₃ and the fourth port P₄ and having the electrical resistance R₂.

At this point, in order to characterize completely the divider/combiner 50 it is necessary to evaluate the four variables R₁, R₂, Z₁ and Z₂.

For this purpose it is necessary to set the following conditions:
the power present on the second port P₂, the power present on the third port P₃, and the power present on the fourth port P₄ must all be equal to one another; and
the sum of the powers present on the second port P₂, on the third port P₃, and on the fourth port P₄ must be equal to the power present on the first port P₁.

Furthermore, considering that on each of the three division/combination branches 501, 502 and 503 in each of the two respective stages (TL₁₁ and TL₁₂; TL₂₁ and TL₂₂; TL₃₁ and TL₃₂) there travels a corresponding voltage wave equal to

Vᵢⱼ=Vᵢⱼ⁺+Vᵢⱼ⁻

and a corresponding current wave equal to

Iᵢⱼ=(Iᵢⱼ⁺+Iᵢⱼ⁻)Tiⱼ

with i=1,2,3, which indicates the division/combination branch, and with j=1,2, which indicates the stage, it is necessary to set the Kirchhoff laws in the respective nodes across the uncoupling resistors 504 (N₁ and N₂), 505 (N₂, N₃), 506 (P₂ and P₃), 507 (P₃ and P₄) to guarantee uncoupling between the division/combination branches 501, 502 and 503. In fact, to obtain a good uncoupling between two division/combination branches coupled in a node it is sufficient that in said node the voltage waves of the two division/combination branches are equivalent.

Finally, to guarantee a good matching of the ports, in order to reduce the reflection losses, it is necessary to impose that the impedance seen by the first port P₁ is equal to Z₀.

All the aforesaid conditions imposed lead to:

Z₁=(3 Z₀)3/4Z_{L}^{1/4}

Z₂=(3 Z₀)^{1/4}Z_{L}^{3/4}

R₁=(Z₂²/Z_{L})0.75

R₂=4Z_{L}

Illustrated instead in FIG. 6 is a circuit diagram of a five-way divider/combiner 60 according to the present invention.

In detail, the divider/combiner 60 functions in a frequency band comprised between 8.5 GHz and 10 GHz and, as illustrated in FIG. 6, comprises:
a first port P₁, coupled to a first transmission line 61 having a characteristic impedance Z₀;
a second port P₂, coupled to a first electrical load 62 having an impedance Z_{L};
a third port P₃, coupled to a second electrical load 63 having the impedance Z_{L};
a fourth port P₄, coupled to a third electrical load 64 having the impedance Z_{L};
a fifth port P₅, coupled to a fourth electrical load 65 having the impedance Z_{L};
a sixth port P₆, coupled to a fifth electrical load 66 having the impedance Z_{L};
a first division/combination branch 601, coupled between the first port P₁ and the second port P₂;
a second division/combination branch 602, coupled between the first port P₁ and the third port P₃;
a third division/combination branch 603, coupled between the first port P₁ and the fourth port P₄;
a fourth division/combination branch 604, coupled between the first port P₁ and the fifth port P₅; and
a fifth division/combination branch 605, coupled between the first port P₁ and the sixth port P₆.

Furthermore, the first division/combination branch 601 is divided into a first stage TL₁₁ and a second stage TL₁₂ and comprises an intermediate node N₁, the first stage TL₁₁ being constituted by a transmission line coupled between the first port P₁ and the intermediate node N₁ and having a characteristic impedance equal to Z₁, and an electrical length equal to λ/4 or 3λ/4, wherein λ is the wavelength corresponding to the middle frequency of the frequency band [8.5 GHz; 10 GHz] of the RF signals for the propagation of which the divider/combiner 60 is designed, the second stage TL₁₂ being constituted by a transmission line coupled between the intermediate node N₁ and the second port P₂ and having a characteristic impedance equal to Z₂ and an electrical length equal to λ/4 or 3λ/4.

Also the second division/combination branch 602 is divided into a first stage TL₂₁ and a second stage TL₂₂ and comprises an intermediate node N₂, the first stage TL₂₁ being constituted by a transmission line coupled between the first port P₁ and the intermediate node N₂ and having the characteristic impedance Z₁ and an electrical length equal to λ/4 or 3λ/4, the second stage TL₂₂ being constituted by a transmission line coupled between the intermediate node N₂ and the third port P₃ and having the characteristic impedance Z₂ and an electrical length equal to λ/4 or 3λ/4.

Likewise, also the third division/combination branch 603 is divided into a first stage TL₃₁ and a second stage TL₃₂ and comprises an intermediate node N₃, the first stage TL₃₁ being constituted by a transmission line coupled between the first port P₁ and the intermediate node N₃ and having the characteristic impedance Z₁ and an electrical length equal to λ/4 or 3λ/4, the second stage TL₃₂ being constituted by a transmission line coupled between the intermediate node N₃ and the fourth port P₄ and having the characteristic impedance Z₂ and an electrical length equal to λ/4 or 3λ/4.

Once again as illustrated in FIG. 6, also the fourth division/combination branch 604 is divided into a first stage TL₄₁ and a second stage TL₄₂ and comprises an intermediate node N₄, the first stage TL₄₁ being constituted by a transmission line coupled between the first port P₁ and the intermediate node N₄, and having the characteristic impedance Z₁ and an electrical length equal to λ/4 or 3λ/4, the second stage TL₄₂ being constituted by a transmission line coupled between the intermediate node N₄ and the fifth port P₅, and having the characteristic impedance Z₂ and an electrical length equal to λ/4 or 3λ/4.

Furthermore, also the fifth division/combination branch 605 is divided into a first stage TL₅₁ and a second stage TL₅₂ and comprises an intermediate node N₅, the first stage TL₅₁ being constituted by a transmission line coupled between the first port P₁ and the intermediate node N₅, and having the characteristic impedance Z₁ and an electrical length equal to λ/4 or 3λ/4, the second stage TL₅₂ being constituted by a transmission line coupled between the intermediate node N₅ and the sixth port P₆ and having the characteristic impedance Z₂ and an electrical length equal to λ/4 or 3λ/4.

Finally, the divider/combiner 60 also comprises:
a first uncoupling resistor 606, coupled between the intermediate node N₁ and the intermediate node N₂ and having an electrical resistance equal to R₁;
a second uncoupling resistor 607, coupled between the intermediate node N₂ and the intermediate node N₃ and having the electrical resistance R₁;
a third uncoupling resistor 608, coupled between the intermediate node N₃ and the intermediate node N₄ and having the electrical resistance R₁;
a fourth uncoupling resistor 609, coupled between the intermediate node N₄ and the intermediate node N₅ and having the electrical resistance R₁;
a fifth uncoupling resistor 610, coupled between the second port P₂ and the third port P₃ and having an electrical resistance equal to R₂;
a sixth uncoupling resistor 611, coupled between the third port P₃ and the fourth port P₄ and having the electrical resistance R₂;
a seventh uncoupling resistor 612, coupled between the fourth port P₄ and the fifth port P₅ and having the electrical resistance R₂; and
an eighth uncoupling resistor 613, coupled between the fifth port P₅ and the sixth port P₆ and having the electrical resistance R₂.

If we set for the divider/combiner 60 conditions similar to those set for the divider/combiner 50 we obtain

Z₁=(5Z₀)^{3/4}Z_{L}^{1/4}

Z₂=(5Z₀)^{1/4}Z_{L}^{3/4}

R₁=(Z₂²/Z_{L}) 0.4

R₂=3Z_{L}

Preferably, both in the divider/combiner 50 and in the divider/combiner 60, the first stages of the division/coupling branches have an electrical length equal to 3λ/4 rather than λ/4 in order to maintain an appropriate distance between the different stages TLᵢⱼ of the division/combination branches to prevent undesirable coupling phenomena.

The aim here is to emphasize how the N-way divider/combiner, with N≠2^{K}, according to the present invention will enable optimal electrical performance in terms of balancing of amplitude and phase and of insulations and losses by transmission and reflection, electrical performance that is comparable with that of Wilkinson dividers/combiners and clearly better, above all for applications in avionic radars with electronic beam-scanning antenna, than those of power dividers/combiners belonging to other known topologies.

Furthermore, the N-way divider/combiner, with N≠2^{K}, according to the present invention can be obtained in totally planar, monolithic, and single-face technology, unlike N-way Wilkinson dividers/combiners, with N≠2^{K}, which, instead, do not enable a totally planar embodiment on account of the presence of uncoupling resistors, which cannot be obtained all in one and the same plane.

In this regard, described in detail in what follows is a method for manufacturing the N-way divider/combiner, with N≠2^{K}, according to the present invention.

In particular, the method for manufacturing the N-way power divider/combiner, with N≠2^{K}, according to the present invention comprises:
forming a multilayer structure comprising a conductive layer, a resistive layer underneath the conductive layer, and a dielectric substrate underneath the resistive layer;
chemically etching and removing selectively first portions of said conductive layer and first portions of said resistive layer, which are underneath the first portions of said conductive layer, to form the N division/combination branches; and
chemically etching and removing selectively second portions of said conductive layer to form the first and second uncoupling resistors.

In what follows, the manufacturing method is described with explicit reference to organic laminates, it remaining, however, understood that what will be described can be applied, with the appropriate variations, for example by replacing the lamination with a firing process, also on ceramic substrate with a base of Al₂O₃ (alumina) or AlN (aluminium nitride), both in thin-film and thick-film configuration.

Hence, preferably, forming a multilayer structure comprises:
electrodepositing the resistive layer on the conductive layer; and
laminating the resistive layer and the conductive layer on the dielectric substrate.

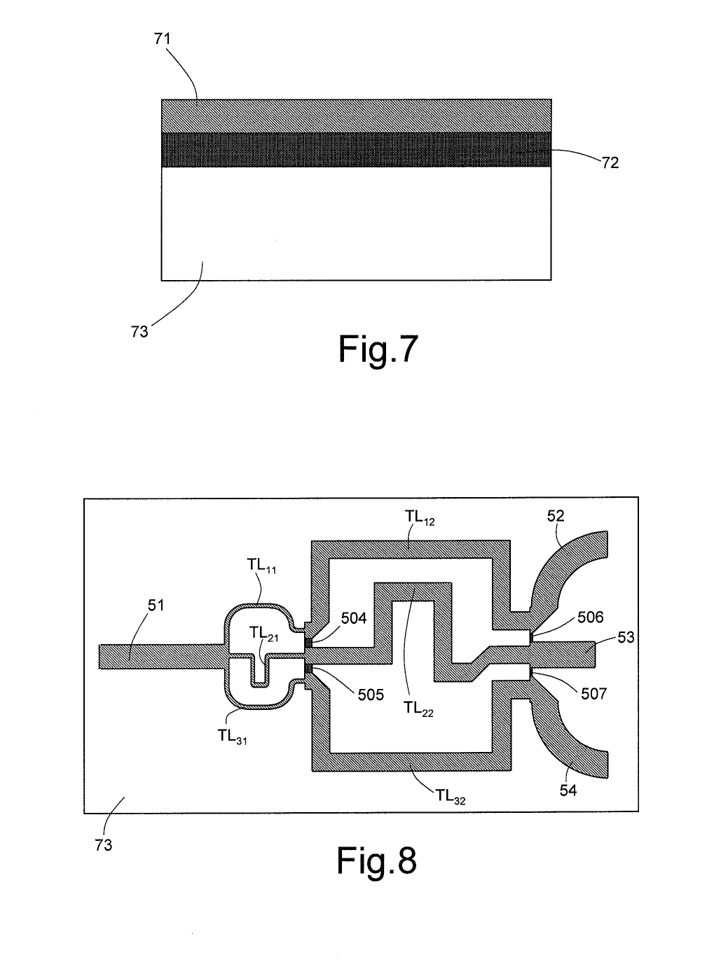

In this regard, illustrated in FIG. 7 is a cross section of a multilayer structure 70 with which the N-way power divider/combiner, with N≠2^{K}, according to the present invention, may be obtained.

In detail, as illustrated in FIG. 7, the multilayer structure 70 comprises a conductive layer 71 upon a resistive layer 72, which is in turn set upon a dielectric substrate 73.

Preferably, the dielectric substrate is a so-called noble substrate, i.e., one that can be used even in the microwave range, for example made of PTFE (polytetrafluoroethylene); conveniently, the substrate Rogers RT6002 having a thickness of 0.635 mm may be used.

Conveniently, further, as resistive layer the resistive layer Omega Ply may be used.

Preferably, chemically etching and removing selectively first portions of said conductive layer and first portions of said resistive layer comprises:
forming on the conductive layer a first mask which selectively covers the second portions of said conductive layer and third portions of said conductive layer and exposes the first portions of said conductive layer, the third portions of said conductive layer defining the N division/combination branches, the second portions of said conductive layer being on top of second portions of said resistive layer, which define the first and second uncoupling resistors;
chemically etching and removing the first portions of said conductive layer so as to leave the underneath first portions of said resistive layer exposed;
chemically etching and removing the first portions of said resistive layer so as to leave underneath portions of said dielectric substrate exposed; and
chemically etching and removing the first mask.

Furthermore, preferably, chemically etching and removing selectively second portions of said conductive layer comprises:
forming a second mask which selectively covers the third portions of said conductive layer and exposes the second portions of said conductive layer;
chemically etching and removing the second portions of said conductive layer so as to leave the underneath second portions of said resistive layer exposed; and
chemically etching and removing the second mask.

Conveniently, forming a first mask on the conductive layer comprises:
applying a first photoresist layer on the conductive layer;
exposing selectively portions of said first photoresist layer to a first UV radiation in such a way as to define said first mask; and
developing said first photoresist layer.

Furthermore, conveniently, forming a second mask comprises:
applying a second photoresist layer on the second and third portions of said conductive layer;
exposing portions of said second photoresist layer selectively to a second UV radiation in such a way as to define said second mask; and
developing said second photoresist layer.

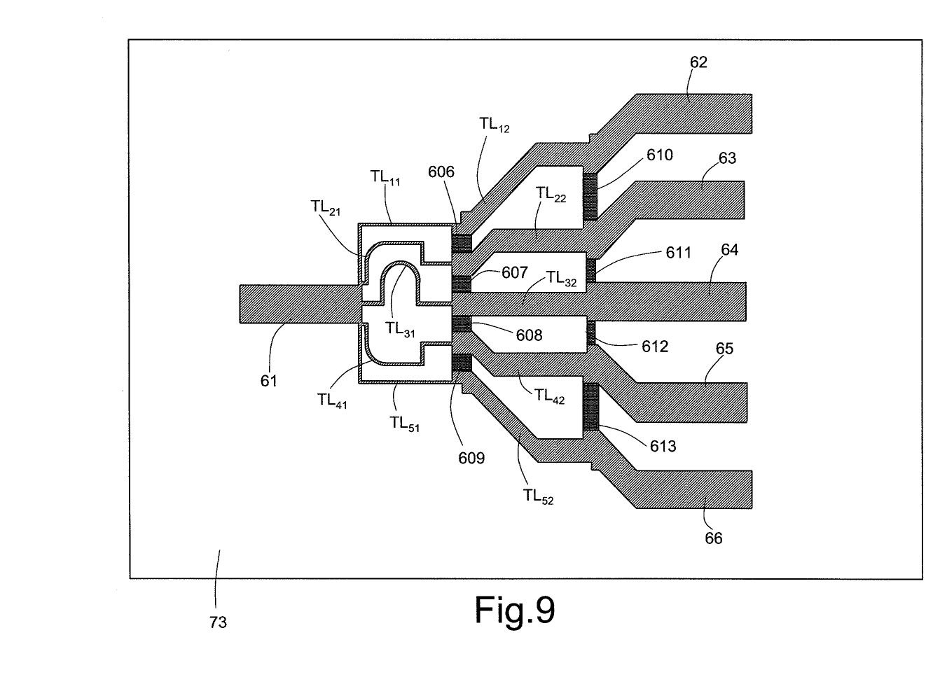

Finally, illustrated in FIG. 8 and in FIG. 9 are top plan views, respectively, of the divider/combiner 50 and of the divider/combiner 60 obtained in totally planar, monolithic, and single-face technology.

In particular, in FIGS. 8 and 9 the components of the divider/combiner 50 and of the divider/combiner 60 are identified with the same reference numbers used, respectively, in FIG. 5 and in FIG. 6.

From the foregoing description the advantages of the present invention may be readily understood.

In the first place, the power divider/combiner according to the present invention enables excellent results to be obtained in terms of insertion losses, insulation between the output ports, phase and amplitude balancing and reflection losses, results that are comparable with those of the Wilkinson divider/combiner.

Another advantage is linked to the fact that the divider/combiner according to the present invention is able to withstand powers in the region of approximately 5 W, said powers being perfectly congruous with those usually present in distribution networks for electronic beam-scanning avionic radars operating at frequencies comprised between 8.5 GHz and 10 GHz.

Furthermore, unlike N-way Wilkinson dividers/combiners with N≠2^{K}, the divider/combiner according to the present invention can be obtained in totally planar, monolithic, and single-face technology, and the topology of the divider/combiner according to the present invention is suited also to its embodiment in stripline, as well as in microstrip, which increases the possibilities of application thereof considering that the first propagation structure increases the packing factor because immunity to EM (electromagnetic) disturbance is increased.

On the other hand, the divider/combiner according to the present invention comprises integrated resistors and consequently does not require any machining subsequent to the production of the card itself, such as for example bonding of components, wiring, etc.

This enables a considerable reduction in production times and costs, as well as an increase in terms of reliability and resistance to the environmental screening of the cards, which are also more manageable.

Furthermore, the complete structure is more compact and requires lower transmission power, and, thanks to the high levels of electrical performance, also the radiation pattern is more precise and the overall noise figure of the system is lower.

A further advantage is linked to the fact that the divider/combiner according to the present invention enables distribution networks and hence antenna arrays with an arbitrary number of radiators to be provided, thus eliminating the constraint of considering quantities equal to powers of two.

Finally, it is clear that various modifications may be made to the present invention, all of which fall within the sphere of protection of the invention defined in the annexed claims.

What is claimed is:

1. A planar N-way power divider/combiner (50, 60), wherein N is an integer different from a power of two (N≠2^{K}, wherein K=1,2,3,4, . . . ), comprising:
a first port (P₁) intended to be coupled to a first transmission line (51, 61) having a first characteristic impedance (Z₀);
N second ports (P₂, P₃, P₄, P₅, P₆) each intended to be coupled to a corresponding electrical load (52, 53, 54, 62, 63, 64, 65, 66), all the electrical loads (52, 53, 54, 62, 63, 64, 65, 66) having one and the same given load impedance (Z_{L}); and
N division/combination branches (501, 502, 503, 601, 602, 603, 604, 605) each coupled between the first port (P₁) and a corresponding second port (P₂, P₃, P₄, P₅, P₆); the planar N-way power divider/combiner (50, 60) being configured to:
divide a first electrical signal present as input at the first port (P₁) into N second electrical signals;
output each of the N second electrical signals at a corresponding second port (P₂, P₃, P₄, P₅, P₆);
combine N third electrical signals each present as input at a corresponding second port (P₂, P₃, P₄, P₅, P₆) into a fourth electrical signal; and
output said fourth electrical signal at the first port (P₁);
the planar N-way power divider/combiner (50, 60) being characterized in that each of the N division/combination branches (501, 502, 503, 601, 602, 603, 604, 605) comprises a corresponding first stage (TL₁₁, TL₂₁, TL₃₁, TL₄₁, TL₅₁), a corresponding second stage (TL₁₂, TL₂₂, TL₃₂, TL₄₂, TL₅₂), and a corresponding intermediate node (N₁, N₂, N₃, N₄, N₅) between the corresponding first stage (TL₁₁, TL₂₁, TL₃₁, TL₄₁, TL₅₁) and the corresponding second stage (TL₁₂, TL₂₂, TL₃₂, TL₄₂, TL₅₂);
the planar N-way power divider/combiner (50, 60) being further characterized by comprising also:
for each pair of planarly adjacent division/combination branches (501, 502, 503, 601, 602, 603, 604, 605), a corresponding first uncoupling resistor (504, 505, 606, 607, 608, 609) coupled between the corresponding intermediate nodes (N₁, N₂, N₃, N₄, N₅), and a corresponding second uncoupling resistor (506, 507, 610, 611, 612, 613) coupled between the corresponding second ports (P₂, P₃, P₄, P₅, P₆).

2. The planar N-way power divider/combiner of claim 1, wherein the first electrical signal has a first power and a first frequency comprised in a given frequency band, and wherein all the second electrical signals have the first frequency and one and the same second power which is equal to the first power divided by N; all the third electrical signals having one and the same third power and one and the same second frequency comprised in the given frequency band, the fourth electrical signal having the second frequency and a fourth power which is equal to N times the third power;
all the first uncoupling resistors (504, 505, 606, 607, 608, 609) having one and the same first electrical resistance (R₁);
all the second uncoupling resistors (506, 507, 610, 611, 612, 613) having one and the same second electrical resistance (R₂);
in each of the N division/combination branches (501, 502, 503, 601, 602, 603, 604, 605) the corresponding first stage (TL₁₁, TL₂₁, TL₃₁, TL₄₁, TL₅₁) comprising a corresponding second transmission line coupled between the first port (P₁) and the corresponding intermediate node (N₁, N₂, N₃, N₄, N₅);
in each of the N division/combination branches (501, 502, 503, 601, 602, 603, 604, 605) the corresponding second stage (TL₁₁, TL₂₂, TL₃₂, TL₄₂, TL₅₂) comprising a corresponding third transmission line coupled between the corresponding intermediate node (N₁, N₂, N₃, N₄, N₅) and the corresponding second port (P₂, P₃, P₄, P₅, P₆);
all the second transmission lines having one and the same second characteristic impedance (Z₁) and one and the same first electrical length;
all the third transmission lines having one and the same third characteristic impedance (Z₂) and one and the same second electrical length;
the first electrical length being an odd multiple of a quarter of a predefined wavelength (λ) which corresponds to a middle frequency in the given frequency band; and
the second electrical length being an odd multiple of a quarter of a predefined wavelength (λ) which corresponds to a middle frequency in the given frequency band.

3. The planar N-way power divider/combiner of claim 2, wherein the first electrical length is equal to one quarter or to three quarters of the predefined wavelength (λ).

4. The planar N-way power divider/combiner of claim 2, wherein the second electrical length is equal to one quarter or to three quarters of the predefined wavelength (λ).

5. The planar N-way power divider/combiner according to claim 2, wherein the first frequency and the second frequency are radio frequencies.

6. The planar N-way power divider/combiner according to claim 2, wherein the given frequency band is comprised between 8.5 GHz and 10 GHz.

7. The planar N-way power divider/combiner according to claim 2, wherein N is equal to three, and wherein the second characteristic impedance (Z₁) is equal to
(3Z₀)^{3/4}*Z_{L}^{1/4},
wherein Z₀ denotes the first characteristic impedance, and Z_{L} denotes the given load impedance;
the third characteristic impedance (Z₂) being equal to
(3Z₀)^{1/4}*Z_{L}^{3/4},

8. The planar N-way power divider/combiner of claim 7, wherein the first electrical resistance (R₁) is equal to
(Z₂²/Z_{L})*0.75,
wherein Z₂ denotes the third characteristic impedance;
the second electrical resistance (R₂) being equal to 4Z_{L}.

9. The planar N-way power divider/combiner according to claim 2, wherein N is equal to five, and wherein the second characteristic impedance (Z₁) is equal to
(5Z₀)^{3/4}*Z_{L}^{1/4},
wherein Z₀ denotes the first characteristic impedance, and wherein Z_{L} denotes the given load impedance;
the third characteristic impedance (Z₂) being equal to
(5Z₀)^{1/4}*Z_{L}^{3/4}.

10. The planar N-way power divider/combiner of claim 9, wherein the first electrical resistance (R₁) is equal to
(Z₂²/Z_{L})*0.4,
wherein Z₂ denotes the third characteristic impedance;
the second electrical resistance (R₂) being equal to 3Z_{L}.

11. A method of manufacturing the planar N-way power divider/combiner according to claim 1, the method comprising:
forming a multilayer structure comprising a conductive layer (71), a resistive layer (72) underneath the conductive layer (71), and a dielectric substrate (73) underneath the resistive layer (72);
chemically etching and removing, selectively, first portions of said conductive layer (71) and first portions of said resistive layer (72) which are underneath the first portions of said conductive layer (71) in order to form the N division/combination branches (501, 502, 503, 601, 602, 603, 604, 605); and
chemically etching and removing, selectively, second portions of said conductive layer (71) in order to form the first (504, 505, 606, 607, 608, 609) and the second (506, 507, 610, 611, 612, 613) uncoupling resistors.

12. The method of claim 11, wherein forming a multilayer structure comprises:
electrodepositing the resistive layer (72) on the conductive layer (71); and
laminating the resistive layer (72) and the conductive layer (71) on the dielectric substrate (73).

13. The method of claim 11, wherein chemically etching and removing, selectively, first portions of said conductive layer (71) and first portions of said resistive layer (72) comprises:
forming on the conductive layer (71) a first mask which, selectively, covers the second and third portions of said conductive layer (71) and exposes the first portions of said conductive layer (71), the third portions of said conductive layer (71) defining the N division/combination branches (501, 502, 503, 601, 602, 603, 604, 605), the second portions of said conductive layer (71) being upon second portions of said resistive layer (72) defining the first (504, 505, 606, 607, 608, 609) and the second (506, 507, 610, 611, 612, 613) uncoupling resistors;
chemically etching and removing the first portions of said conductive layer (71) so as to leave exposed the underneath first portions of said resistive layer (72);
chemically etching and removing the first portions of said resistive layer (72) so as to leave exposed underneath portions of said dielectric substrate (73); and
chemically etching and removing the first mask.

14. The method of claim 13, wherein chemically etching and removing, selectively, second portions of said conductive layer (71) comprises:
forming a second mask which, selectively, covers the third portions of said conductive layer (71) and exposes the second portions of said conductive layer (71);
chemically etching and removing the second portions of said conductive layer (71) so as to leave exposed the underneath second portions of said resistive layer (72); and
chemically etching and removing the second mask.

15. The method of claim 14, wherein forming on the conductive layer (71) a first mask comprises:
applying a first photoresist layer on the conductive layer (71);
selectively exposing portions of said first photoresist layer to a first UV radiation so as to define said first mask; and
developing said first photoresist layer;
and wherein forming a second mask comprises:
applying a second photoresist layer on the second and the third portions of said conductive layer (71);
selectively exposing portions of said second photoresist layer to a second UV radiation so as to define said second mask; and
developing said second photoresist layer.
